(19) United States
(12) Patent Application Publication
(10) Pub. No.: US 2012/0152332 A1
(43) Pub. Date: Jun. 21, 2012

(54) SOLAR BATTERY ASSEMBLY AND METHOD FOR FORMING THE SAME

(76) Inventor: Hui LUO, Shenzhen (CN)

(21) Appl. No.: 13/406,831

(22) Filed: Feb. 28, 2012

Related U.S. Application Data
(63) Continuation of application No. PCT/CN2010/076445, filed on Aug. 29, 2010.

(30) Foreign Application Priority Data
Aug. 31, 2009 (CN) 200910189801.6
Aug. 31, 2009 (CN) 200920204199.4

(51) Int. Cl. H01L 31/048; H01L 31/18

(52) U.S. Cl. 136/251; 438/66; 257/E31.11

(57) ABSTRACT

A method for forming a solar battery assembly is provided, comprising: a) performing cold vacuuming at a temperature ranging from about 0° C. to about 50° C. and hot vacuuming at a temperature ranging from about 50° C. to about 200° C. to a glass plate, a plurality of solar cells and a back sheet that are laminated in turn and adhered together; and b) treating the laminated glass plate, plurality of solar cells and back sheet obtained in step (a) at a temperature ranging from about 100° C. to about 200° C. and a pressure ranging from about 0.5 MPa to about 1.5 MPa to obtain the solar battery assembly. A solar battery assembly is also provided.

### CROSS-REFERENCE TO RELATED APPLICATIONS

The present application is a continuation of International Application No. PCT/CN2010/076445, filed Aug. 29, 2010, designating the United States of America, which claims priority to and benefits of Chinese Patent Application Nos. 200920204199.4 and 200910189801.6, both filed with the China Patent Office on Aug. 31, 2009. The contents of all the above-referenced applications are incorporated herein by reference in their entirety.

### FIELD

The present disclosure relates to solar battery, and in particular to a method for forming a solar battery assembly and a solar battery assembly which may be used as an automobile roof.

### BACKGROUND

With continuous consumption of limited traditional energy resources such as oil which resulted in serious pollution to the environment, utilization of wind and solar energy has become increasingly popular. Particularly, the abundance of solar energy with less geological restriction has rendered solar energy a hot and important research focus nowadays.

Meanwhile, new energy vehicles with less environmental pollution have become a development trend for future automobiles. They are not only environment amicable but also less reliant on non-renewable natural energy. Current new energy vehicles mainly employ lithium ion batteries, fuel batteries or hydrogen storage batteries as their power supply.

To thoroughly utilize the safe and inexhaustible solar energy, solar batteries can now be applied on vehicles. However, the back sheets of existing solar batteries are normally flexible and therefore difficult to be installed on the vehicle. Besides, existing solar batteries may occupy large space in the vehicle, resulting in higher vehicle weight and less favorable external appearance. For at least the above reasons, solar batteries have not been widely adopted nowadays.

Current solar battery assembly may be formed by overlapping and adhering together a glass plate, a plurality of solar cells, and a flexible back sheet, and then heating and laminating these layers to form the solar battery assembly.

Normally the laminated layers of the glass plate, the solar cells and the flexible back plate may be placed on a heating mold of a laminating machine for heating. And an elastic layer on a top cover of the laminating machine may be used for dynamic laminating of the solar battery assembly. However, the aforementioned method may have difficulty in controlling the laminating conditions for forming a solar battery assembly having a hard back sheet with attractive appearance and excellent performance. Because the elastic layer may bear uneven pressures at different positions, and also because of the self weight of the flexible back sheet, it is difficult to ensure uniform forces on the solar battery assembly to be formed. When the back sheet is a hard one, uneven dynamic pressures may cause problems such as breakage of the solar cells, uneven binding agents caused by uneven pressures, and gas bubble residues. However, the solar battery assembly may have a high requirement for air-tightness. The existence of bubbles or uneven thickness of the binding agent may seriously affect the performance of the solar battery. Especially for current solar batteries for vehicles, which normally adopt an arch shape, the performance requirement may be even stricter, and it is difficult to develop a desirable laminating process.

It has been disclosed that the assembly may be placed on a heating plate of an arch shaped mold and laminated with a flexible layer; however, solar battery assemblies with limited types of shapes may be prepared due to the restriction of the mold. Also the process is not beneficial for large scale production due to its relatively low efficiency and high cost. For solar battery assemblies with a hard back sheet, the mold may need to be well attached with the back sheet, and meanwhile the temperature of the heating plate may need to be stable which is difficult to realize. Moreover, the laminating result may still have problems such as bubbles and uneven thickness of the binding agent. The solar battery assembly thus produced with a low yield may not meet the industrial application demand.

### SUMMARY

Provided herein are methods for forming a solar battery assembly with increased performance and yield rate, and the solar battery assembly manufactured therefrom.

According to an aspect of the present disclosure, a method for forming a solar battery assembly may be provided, comprising:

a) performing cold vacuuming at a temperature ranging from about 0° C. to about 50° C. and hot vacuuming at a temperature ranging from about 50° C. to about 200° C. to a glass plate, a plurality of solar cells and a back sheet that are laminated in turn and adhered together; and

b) treating the laminated glass plate, plurality of solar cells and back sheet obtained in step (a) at a temperature ranging from about 100° C. to about 200° C. and a pressure ranging from about 0.5 MPa to about 1.5 MPa to obtain the solar battery assembly.

The method described herein may increase the yield rate and decrease the occurrence of bubbles, solar cell fragments, or uneven binding agents. The solar battery assembly thus manufactured may have better appearance and mechanical performance. The method may achieve a consistent matching between the layers in the solar battery assembly suitable for industrial development.

The present disclosure may adopt a non-contact static laminating process with high pressure. For example, in some embodiments, a gas static laminating method may be adopted which may be more gentle and easier to locate according to the shape of the solar battery assembly. Also fragmentation of the solar cells may be easily prevented. By exerting pressure on two surfaces of the solar battery assembly, the method may increase the internal and external pressure differences to achieve thorough lamination, wherein fog-like bubbles may be easily absorbed by the binding agent. The method may reduce the occurrence of bubbles in the solar battery assembly and thereby prevent the influence of micro bubbles on the performance of the solar battery. Therefore, the method according to the present disclosure may provide solar batteries with a hard back sheet with enhanced appearance and extended applicability.

The method according to the present disclosure may solve the problem in laminating arch shaped solar battery assemblies. The method disclosed herein may be simpler and easier to realize, and the manufacturing cost thereof may be reduced to a great extent. The arch shaped solar battery assembly thus formed may have enhanced appearance with improved performance, without solar cell fragments. Moreover, solar battery assemblies with various shapes may be formed using present method without the need for different molds.

Furthermore, the method disclosed herein may be particularly applicable for solar battery assemblies comprising an electrode circuit and a diode protection circuit laid inside the solar battery assembly for laminating. The electronic components such as diodes may be fragile and easily broken. In addition, relative movement of the solar cells may occur inside existing solar battery assemblies under dynamic pressure, which may damage the circuit and the diode and further affect the battery performance. However, the method disclosed herein may adopt a non-contact static laminating process based on the original shape of the solar battery assembly. The uniform gas pressure applied herein may effectively prevent the relative movement of solar cells. In addition, the present method may be suitable for large scale production.

According to another aspect of the present disclosure, a solar battery assembly may be provided. The solar battery assembly may be used as an automobile roof, comprising an arched light transmitting upper cover plate, an arched back sheet, and a plurality of solar cells disposed between the arched light transmitting upper cover plate and the arched back sheet. The arched light transmitting upper cover plate, the arched back sheet and the plurality of the solar cells may be adhered together by filling a binding agent between the upper cover plate and the back sheet.

The arched back sheet may have a Mohs hardness of at least 1.

The solar battery assembly used as an automobile roof may be easily installed on an automobile to receive external light and power the vehicle efficiently. And it may also decrease the total weight of the vehicle.

Additional aspects and advantages of the embodiments of present invention will be given in part in the following descriptions, become apparent in part from the following descriptions, or be learned from the practice of the embodiments of the present invention.

### BRIEF DESCRIPTION OF THE DRAWINGS

These and other aspects and advantages of the invention will become apparent and more readily appreciated from the following descriptions taken in conjunction with the drawings in which:

FIG. 1 is a plan view of a solar battery array according to an embodiment of the present disclosure.

### DETAILED DESCRIPTION OF THE EMBODIMENTS

The aforementioned features and advantages of the present disclosure as well as the additional features and advantages thereof will be further clearly understood hereafter as a result of a detailed description of the following embodiments.

The present disclosure may provide a method for forming a solar battery assembly which may be easily performed with increased production efficiency and yield rate. The thus prepared solar battery assembly may possess attractive appearance and enhanced mechanical performance.

According to some embodiments of the present disclosure, the method may comprise the following steps:

a) performing cold vacuuming at a temperature ranging from about 0° C. to about 50° C. and hot vacuuming at a temperature ranging from about 50° C. to about 200° C. to a glass plate, a plurality of solar cells and a back sheet that are laminated in turn and adhered together; and

b) treating the laminated glass plate, plurality of solar cells and back sheet obtained in step (a) at a temperature ranging from about 100° C. to about 200° C. and a pressure ranging from about 0.5 MPa to about 1.5 MPa to obtain the solar battery assembly.

The above mentioned method may inhibit the occurrence of bubbles during lamination and provide an enhanced external appearance, especially for solar battery assemblies with a hard back sheet. The difficulty in laminating an arch shaped solar battery assembly may be overcome. And the arch shaped solar battery assembly thus formed may have a better appearance. Particularly, solar battery components with different shapes may be obtained without the need for different molds.

According to some embodiments, the cold vacuuming may be performed at a temperature ranging from about 20° C. to about 30° C. for a time period ranging from about 10 min to about 15 min, with a pressure decreasing speed ranging from about 90 KPa/min to about 100 KPa/min and a vacuuming degree ranging from about −50 KPa to about −101 KPa. In some embodiments, the hot vacuuming may be performed at a temperature ranging from about 90° C. to about 110° C. for a period of time ranging from about 10 min to about 120 min with a vacuum degree ranging from about −50 PKa to about −101 KPa. In some embodiments, the hot vacuuming may be performed by heating in multistage during which the temperature may or may not be the same in different stages. When the heating time is divided in a plurality of stages of hot vacuuming, the bubbles in the solar battery assembly may be expelled to a greater extent.

The vacuuming may be performed according to any vacuuming method known in the art. According to some embodiments of the present disclosure, the laminated glass plate, plurality of the solar cells and back sheet may be placed in a vacuuming chamber to perform the vacuuming. According to some embodiments, a sealing member, such as an encapsulating cover, formed with apertures may be provided around edges of the solar battery assembly, and then vacuuming may be performed via the apertures. The vacuuming speed may thereby be enhanced. The method may effectively reduce bubbles in the solar battery assembly without negative effects. Furthermore, compared with existing vacuuming methods in which the vacuuming process is not viewable, the above mentioned method may provide a solution for a secondary vacuuming or troubleshooting, and it is beneficial for quality control in each step and the final assembly. The devices used in the method may also be simpler.

According to some embodiments, step (b) may further comprise placing the vacuumed solar battery assembly obtained in step (a) into a reactor in which the temperature and pressure are increased, maintained for a predetermined time and then decreased. The temperature and pressure of the reactor may be increased in a multistage manner. For example, before reaching a desired high temperature and high pressure, the solar battery assembly may undergo a plurality of stages of lower temperature and lower pressure treatment. The lower temperature and pressure may be maintained for several minutes, such as 3 min to 5 min, to optimize the subsequent high temperature and high pressure treatment. According to some embodiments, the starting temperature for increasing the temperature may range from about 20° C. to about 30° C., and the starting pressure for increasing the pressure may range from about 0 MPa to about 0.1 MPa, such as 0.1 MPa. The terminating or end temperature of the temperature and pressure decreasing step may range from about 50° C. to about 30° C., and the terminating or end pressure thereof may range from about 0 MPa to about 0.1 MPa, to cure the binding agent.

According to some embodiments of the present disclosure, the temperature increasing speed in the reactor may range from about 1° C./min to about 50° C./min, and the pressure increasing speed may range from about 0.01 MPa/min to about 0.2 MPa/min; the temperature decreasing speed in the reactor may range from about 1° C./min to about 50° C./min, and the pressure decreasing speed may range from about 0.01 MPa/min to about 0.2 MPa/min. According to some embodiments, the temperature of the high temperature and high pressure treatment may range from about 130° C. to about 160° C., the pressure thereof may range from about 1.0 MPa to about 1.5 MPa, and the treatment may be performed for a period of time ranging from about 5 min to about 120 min, such as from about 40 min to about 55 min. Using the method disclosed herein, improved solar battery assemblies may be obtained without problems such as solar cell fragments.

The glass plate described herein may be chosen from any light transmitting glass plate known in the art; for example, tempered glass may be used. The back sheet may be chosen from any back sheet known in the art, for example, a glass plate or a steel plate, which may increase the strength of the solar battery and improve the protection of core components in the solar cells to obtain a prolonged battery lifespan. The method according to the present disclosure may be particularly suitable for preparing batteries with a hard back sheet. The high strength of the hard back sheet may help to enhance the pressure difference between the two surfaces of the solar battery assembly under high temperature and high pressure, and to better achieve the final design of the solar battery assembly. According to some embodiments, the back sheet may be a glass plate; therefore, the double glass layers may realize better attachment and eliminate bubbles inside the solar battery assembly, thus improving the performance of the solar battery assembly.

The method according to the present disclosure may be especially suitable for preparing arch shaped solar batteries. For example, the glass plate may have a predetermined curvature. The solar cell may be chosen from any kind known in the art. In some embodiments, the solar cell may be made of monocrystalline silicon or multicrystalline silicon. It may include a single solar cell or a plurality of solar cells connected in parallel. For a solar battery having an arched shape to be used in a vehicle, a plurality of small solar cells may be assembled to form the desired arched shape.

According to some embodiments of the present disclosure, the binding agent for laminating the glass plate, the plurality of solar cells and the back sheet may be chosen from ethylene vinyl acetate (EVA) film and polyvinyl butyral (PVB) film, such as PVB film. The thickness of the binding agent may range from about 0.15 mm to about 1.5 mm, such as 0.76 mm. The size and strength of the battery assembly may thus be improved and fragments of solar cells may be prevented. Especially for solar battery assemblies with a glass plate as the back sheet, the PVB film may be a half transparent film free of impurities and with a smooth surface that also has certain roughness and flexibility. The PVB film may possess an excellent attaching force for inorganic glass. Furthermore, the PVB film may be heat-resistant, cold-resistant, and wet-resistant, and may also have excellent mechanical strength with superior binding property and light transmission.

The solar cell may comprise electrodes for extracting current. In some embodiments, the electrode may be connected with the back sheet. The connection may be achieved by welding. In some embodiments, a printed circuit board (PCB) may be arranged under the back sheet, or the back sheet may be printed with a metal slurry and then sintered to form the desired electrodes. In some embodiments, welding points of welding strips, connecting circuits and diodes, and wire welding points may be arranged on the surface of the back sheet, and a bus line may be extracted therefrom to supply power. Thus, the power current and voltage may be adjusted flexibly, and the solar cells may be fixed stably. Therefore, when the solar battery assembly is used as an automobile roof, the vibration from the vehicle may not affect the battery performance. The solar battery assembly may thus have a prolonged lifespan, and the automobile roof may be maintainable.

According to some embodiments of the present disclosure, a series or a parallel circuit having a voltage of about 14 V may be employed. The circuit having a low voltage may not cause breakdown of the solar cells under the hot spot effect caused by the sunlight shadow, and certain part of the solar cells under the shadow of the sunlight may receive extra heat which may cause reverse breakdown, to further increase the reliability of the solar battery assembly. To solve the hot spot effect, in some embodiments, a bypass diode or bypass diodes may be connected in anti-parallel with a solar battery array formed by solar cells to protect the solar cells inside the solar battery assembly. The bypass diode may be connected in parallel with a current extracting line outside the solar battery assembly or within the solar battery assembly, for example, within the space between the solar cells. By placing the circuits and diodes on the upper surface of the back sheet, problems such as complex wire layout, short circuits or open circuits caused by falling off of the wires may be thereby prevented to enhance the reliability of the solar battery assembly. To increase the battery lifespan, the electrical components may be coated with adhesives or covered with a water-resistant shell to further enhance the battery performance.

The present disclosure may further provide a solar battery assembly formed according to the method described herein, which may serve as an automobile roof. And the automobile roof formed by the solar battery assembly may receive the sunlight and generate energy with an improved external appearance. The solar battery assembly may comprise an arched light transmitting upper cover plate, an arched back sheet, and a plurality of solar cells disposed between the arched light transmitting upper cover plate and the arched back sheet. The arched light transmitting upper cover plate, the arched back sheet and the plurality of the solar cells may be adhered together by filling a binding agent between the upper cover plate and the back sheet.

According to the present disclosure, the curvatures of the light transmitting upper cover plate and the back sheet may be adjusted according to practical requirements. According to some embodiments of the present disclosure, curvatures of the light transmitting upper cover plate and the back sheet may be consistent with each other. In some embodiments, the largest distance between the upper cover plate and the back sheet after attaching may be less than 5 mm. By optimizing the attaching degree between the arched light transmitting upper cover plate and the arched back sheet, the vacuuming process may be performed with improved gas exhaustion.

According to some embodiments of the present disclosure, the lower surface of the arched back sheet may be coated with ink to adjust the background color of the automobile roof to improve the external appearance and light absorption rate thereof.

In some embodiments, the front and back surfaces of the solar cell may be welded by welding strips for extracting negative and positive currents, and the plurality of solar cells may be connected in series, in parallel or in combinations of both by attaching the welding strips with grid lines of electrodes on the front and back surface of the solar cell. According to some embodiments, adhesive tapes may be attached to surfaces of the welding strips and current collecting strips for extracting the current to improve the appearance and applicability of the solar battery assembly.

According to some embodiments, a thin film solar cell may be used with a Mohs hardness of at least 1. In some embodiments, the thin film solar cell may have an arched shape. The arched thin film solar cell may be obtained by coating a thin film of photovoltaic material onto the upper cover plate having an arched shape, for example, coating the thin film of photovoltaic material onto the arched upper cover plate via PVD (physical vapor deposition) in the solar battery assembly which may serve as the automobile roof, so that the production cost may be saved dramatically. When the thin film solar cell is adopted, an arched upper cover plate with various kinds of shapes according to practical requirements may be chosen to finalize the design of the thin solar cell film and the solar cell.

According to some embodiments of the present disclosure, the binding force between the arched upper cover plate and the solar cells and between the solar cells and the arched back sheet may be at least 5 N/cm, thereby preventing bubbles in the obtained automobile roof and improving the appearance and the electro-chemical performance of the automobile roof.

According to some embodiments of the present disclosure, a sealing member, such as a sealing adhesive tape, may be provided around edges of the solar battery assembly which may serve as an automobile roof, and a sealing agent may be disposed between the sealing member and the solar battery assembly to achieve sealing, water-proof, and dust-proof results. During actual use, environmental factors may thus have less impact on the performance and lifespan of the solar battery assembly serving as the automobile roof. According to some embodiments of the present disclosure, the sealing agent may be filled between the sealing member and the solar battery assembly. Further, a groove may be formed on a side of the sealing member facing toward the solar battery assembly to accommodate the edges of the solar battery assembly. And the sealing agent may be filled inside the groove and jointed with the edges of the solar battery assembly so as to tighten the sealing and prevent loosening of the sealing tape during vibration of the vehicle. Thus enhanced sealing performance may help to improve the electro-chemical performance and battery lifespan. The sealing agent may be chosen from any kind known in the art, for example, silica gel and epoxy resin.

The solar battery assembly serving as the automobile roof disclosed herein may have a simplified structure, which is easy for industrialization. Furthermore, it may have an improved appearance with extended applicability.

### Embodiment 1

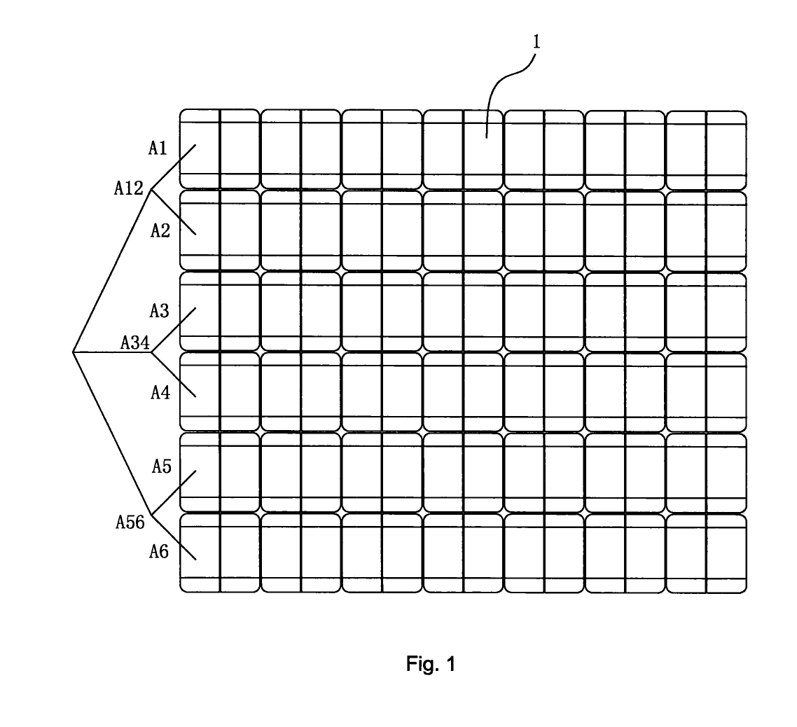

FIG. 1 is a plan view of a solar battery array according to an embodiment of the present disclosure. The solar battery array formed by 6 lines of two series×three parallel (2S3P) connected solar cells (84 in total) designated by 1 was placed between an arched glass light transmitting upper plate having an arc rise of about 20 mm, a size of about 1115 mm×998 mm and a thickness of about 2.0 mm, and an arched glass back sheet having an arc rise of about 20 mm, a size of about 1115 mm×998 mm and a thickness of about 1.6 mm. As shown in FIG. 1, the solar cells 1 in each line were connected in series. And the first and second lines A1 and A2, the third and fourth lines A3 and A4, and the fifth and sixth lines A5 and A6 were connected in series, respectively, whereas the connected lines A12, A34 and A56 were connected in parallel. Each solar cell had a size of about 125 mm×62.5 mm and a designed voltage of about 14 V. The spacing between the solar cells was about 2 mm. The solar battery array had a size of about 961 mm×820 mm. A layer of PVB film with a thickness of about 0.76 mm was disposed between the arched glass light transmitting upper plate and the solar cells, and between the solar cells and the arched glass back sheet. The layers were laminated successively and encapsulated around the edges with a rubber sealing cover formed with apertures. The rubber sealing cover was vacuumed via the apertures at a speed of about 10 KPa/min for about 10 min with a vacuum degree of about −101 KPa. Then the solar battery assembly was hot vacuumed for 8 stages. The temperature and the maintained period of time for each stage were respectively about 90° C. for 225 s; about 95° C. for 255 s; about 100° C. for 300 s; about 105° C. for 300 s; about 110° C. for 300 s; about 115° C. for 300 s; about 120° C. for 315 s; and about 125° C. for 315 s. The vacuum degree ranged from about −100 KPa to about 100 KPa. Then the solar battery assembly was placed into a container for increasing the temperature and the pressure by three stages. In the first stage, the temperature was about 90° C., and the pressure was increased to about 0.1 MPa, which were maintained for a period of time ranging from 9 min to 10 min. In the second stage, the temperature was about 90° C., and the pressure was about 0.1 MPa which were maintained for a period of time ranging from 3 min to 4 min. In the third stage, the temperature was increased to about 150° C., and the pressure was increased to about 1.2 MPa with a whole processing time of about 45 min. After that, high temperature and high pressure treatment was performed, and then the temperature and the pressure were decreased. The high temperature and high pressure treatment was performed at a temperature ranging from about 140° C. to about 158° C. under a pressure of about 1.2 MPa for a period of time ranging from about 40 min to about 50 min. The temperature and the pressure were then decreased at a constant speed to about 30° C. and about 0.1 MPa respectively within a period of time ranging from about 40 to about 45 min.

Electrodes were led out after obtaining the solar battery assembly. And further treatment such as coating with silica gel for encapsulation was performed for forming the solar battery assembly. In the solar battery assembly, there were no bubbles, fog or microbubbles, and there were no fragments of the solar cells. Furthermore, the adhesion between the upper plate and the back sheet was excellent, resulting in a solar battery assembly with an efficiency of about 16.5%.

### Embodiment 2

The solar battery assembly in Embodiment 2 was obtained according to the method described in Embodiment 1, with the exception that the pressure for high temperature and high pressure treatment was about 1.5 MPa. In the solar battery assembly, there were no bubbles, fog or microbubbles, and there were no fragments of the solar cells. Furthermore, the adhesion between the upper plate and the back sheet was excellent, resulting in a solar battery assembly with an efficiency of about 15.5%.

### Embodiment 3

The solar battery assembly in Embodiment 3 was obtained according to the method described in Embodiment 1, with the exception that the pressure for high temperature and high pressure treatment was about 0.5 MPa. In the solar battery assembly, there were no bubbles, fog or microbubbles, and there were no fragments of the solar cells. Furthermore, the adhesion between the upper plate and the back sheet was excellent, resulting in a solar battery assembly with an efficiency of about 14%.

### Comparative Embodiment 1

A solar battery array formed by 6 lines of two series×three parallel (2S3P) connected solar cells (totally 84 PCS) was placed between an arched glass light transmitting upper plate having an arc rise of about 20 mm, a size of about 1115 mm×998 mm and a thickness of about 2.0 mm, and an arched glass back sheet with an arc rise of about 20 mm, a size of about 1115 mm×998 mm and a thickness of about 1.6 mm. Each solar cell had a size of about 125 mm×62.5 mm and a designed voltage of about 14 V. The spacing between the solar cells was about 2 mm. The solar battery array had a size of about 961 mm×820 mm. A layer of PVB film with a thickness of about 0.76 mm was disposed between the arched glass light transmitting upper plate and the solar cells, and between the solar cells and the arched glass back sheet. The layers were laminated successively in a laminating machine which was vacuumed for about 20 min. The assembly was heated to about 140° C. for about 50 min. The glass plate was cracked during processing and the preparation of the solar battery assembly thus failed.

Although explanatory embodiments have been shown and described, it would be appreciated by those skilled in the art that changes, alternatives, and modifications can be made in the embodiments without departing from spirit and principles of the invention. Such changes, alternatives, and modifications all fall into the scope of the claims and their equivalents.

What is claimed is:

1. A method for forming a solar battery assembly, comprising:
(a) performing cold vacuuming at a temperature ranging from about 0° C. to about 50° C. and hot vacuuming at a temperature ranging from about 50° C. to about 200° C. to a glass plate, a plurality of solar cells and a back sheet that are laminated in turn and adhered together; and
(b) treating the laminated glass plate, plurality of solar cells and back sheet obtained in step (a) at a temperature ranging from about 100° C. to about 200° C. and a pressure ranging from about 0.5 MPa to about 1.5 MPa to obtain the solar battery assembly.

2. The method according to claim 1, wherein the cold vacuuming is performed at a temperature ranging from about 20° C. to about 30° C. for a period of time ranging from about 10 min to about 15 min with a pressure decreasing speed ranging from about 90 KPa/min to about 100 KPa/min and a vacuum degree ranging from about −50 KPa to about −101 KPa.

3. The method according to claim 1, wherein the hot vacuuming is performed at a temperature ranging from about 90° C. to about 110° C. for a period of time ranging from about 10 min to about 120 min with a vacuum degree ranging from about −50 PKa to about −101 KPa.

4. The method according to claim 1, wherein the hot vacuuming is performed by heating in multistage.

5. The method according to claim 1, wherein the cold and hot vacuuming are performed by enveloping a sealing member formed with apertures around edges of the laminated glass plate, plurality of solar cells and back sheet so that the solar battery assembly is cold and hot vacuumed via the apertures.

6. The method according to claim 1, wherein step (b) further comprises:
placing the vacuumed solar battery assembly obtained in step (a) into a reactor;
increasing the temperature and the pressure in the reactor in multistage with an initial temperature ranging from about 20° C. to about 30° C. and an initial pressure ranging from about 0 MPa to about 0.1 MPa,
maintaining the temperature and the pressure in the reactor for a period of time; and
decreasing the temperature and the pressure in the reactor with an end temperature ranging from about 50° C. to about 30° C. and an end pressure ranging from about 0 MPa to about 0.1 MPa.

7. The method according to claim 6, wherein the temperature and the pressure in the reactor are increased by a temperature increasing speed ranging from about 1° C./min to about 50° C./min and a pressure increasing speed ranging from about 0.01 MPa/min to about 0.2 MPa/min, respectively; and
wherein the temperature and the pressure in the reactor are decreased by a temperature decreasing speed ranging from about 1° C./min to about 50° C./min and a pressure decreasing speed ranging from about 0.01 MPa/min to about 0.2 MPa/min, respectively.

8. The method according to claim 1, wherein the laminated glass plate, plurality of solar cells and back sheet obtained in step (a) are treated in step (b) at a temperature ranging from about 130° C. to about 160° C. and a pressure ranging from about 1 MPa to about 1.5 MPa for a period of time ranging from about 5 min to about 120 min.

9. The method according to claim 1, wherein the glass plate and the back sheet have an arched shape, and wherein the back sheet is made from a glass plate.

10. The method according to claim 1, wherein the glass plate, the plurality of the solar cells and the back sheet are adhered by polyvinyl butyral or polyethylene vinyl acetate with a thickness ranging from about 0.15 mm to about 1.5 mm.

11. The method according to claim 1, further comprising extracting electrodes on the solar cell for extracting current, welding the electrodes to the back sheet, and connecting a bypass diode with the solar cell in anti-parallel.

12. A solar battery assembly, comprising
an arched light transmitting upper cover plate,
an arched back sheet,
a plurality of solar cells disposed between the arched light transmitting upper cover plate and the arched back sheet, wherein
the arched light transmitting upper cover plate, the arched back sheet and the plurality of the solar cells are adhered together by filling a binding agent between the upper cover plate and the back sheet.

13. The solar battery assembly according to claim 12, wherein the arched light transmitting upper cover plate and the arched back sheet are made from a glass plate respectively.

14. The solar battery assembly according to claim 13, wherein the maximal distance between the arched glass plate and the back sheet is less than 5 mm after assembly.

15. The solar battery assembly according to claim 13, wherein the solar cell is an arched thin film solar cell formed by coating a thin film of photovoltaic material on the arched light transmitting upper cover plate.

16. The solar battery assembly according to claim 12, wherein a lower surface of the back sheet is coated with ink.

17. The solar battery assembly according to claim 12, wherein the solar cell is made of monocrystalline silicon or multicrystalline silicon, and wherein the plurality of solar cells are connected with each other in series, in parallel or in combinations of both.

18. The solar battery assembly according to claim 17, wherein the front and back surfaces of the solar cell are welded with welding strips for extracting negative and positive currents, and the solar cells are connected in series, in parallel or in combinations of both by attaching the welding strips to grid lines of electrodes on the front and back surfaces of the solar cells to be connected, with the surfaces of the welding strips adhered with a tape.

19. The solar battery assembly according to claim 12, wherein binding forces are at least 5 N/cm between the upper cover plate and the solar cells, and between the solar cells and the back sheet.

20. The solar battery assembly according to claim 12, further comprising a sealing member for sealing the light transmitting upper cover plate, the plurality of solar cells and the back sheet laminated together, wherein the sealing member is formed with a groove for accommodating edges of the light transmitting upper cover plate, the plurality of the solar cells and the back sheet laminated together and with a sealing agent filled therein.
